(19) United States
(12) Patent Application Publication
(10) Pub. No.: US 2024/0074321 A1
(43) Pub. Date: Feb. 29, 2024

(54) Dielectric Transducer, Method for the Production Thereof and Actuator, Sensor or Generator

(71) Applicant: Universität des Saarlandes, Saarbrücken (DE)

(72) Inventors: Steffen Hau, Homburg (DE); Stephan Lenz, Saarbrücken (DE); Philipp Linnebach, Illingen (DE); Dennis Meier, St. Wendel (DE); Stefan Seelecke, Saarbrücken (DE)

(21) Appl. No.: 17/767,438

(22) PCT Filed: Oct. 13, 2020
(86) PCT No.: PCT/EP2020/078782

§ 371 Date: Apr. 8, 2022

(30) Foreign Application Priority Data
Oct. 25, 2019 (DE) 102019128822.3

(51) Int. Cl. H10N 30/87; H10N 30/057; H10N 30/063; H10N 30/50; H10N 30/857

(52) U.S. Cl. CPC H10N 30/874; H10N 30/057; H10N 30/063; H10N 30/50; H10N 30/857; H10N 30/875

(57) ABSTRACT

A dielectric transducer for use in a sensor, actuator or generator comprising a plurality of layers of transducer foils, wherein an electrically contactable and conductive layer forming an electrode layer is applied to at least one side of each transducer foil. Expediently, at least two contact elements are provided, each of which is arranged at least partially in a recess or in a through-channel and extends over at least one layer of transducer foils, adjacent electrode layers being electrically conductively connected to different contact elements. Since adjacent electrode layers are connected to different contact elements, intended use is possible, and bringing together several contact lines is advantageously not necessary. Furthermore, the invention relates to a method for producing a multilayer dielectric transducer for use in a sensor, an actuator or a generator, as well as an actuator, a sensor or a generator.

### CROSS REFERENCE TO RELATED APPLICATIONS

This application is the U.S. national stage of International Application No. PCT/EP2020/078782, filed on 2020 Oct. 13. The international application claims the priority of DE 102019128822.3 filed on 2019 Oct. 25; all applications are incorporated by reference herein in their entirety.

### BACKGROUND

The invention relates to a dielectric transducer for use in a sensor or actuator comprising multiple layers of transducer foils, wherein an electrically contactable and conductive electrode layer is applied to at least one side of each transducer foil. Further, the invention relates to a method of making a multilayer dielectric transducer for use in a sensor, actuator, or generator, and to an actuator, sensor, or generator.

Multilayer dielectric transducers for use in actuators, sensors or generators are known from prior art.

Several foils, formed for example from silicone or a plastic containing an acrylic group, are coated on at least one side with an electrically conductive material to form electrodes and afterwards laminated. Electrical contact is made by individually contacting each electrode layer, bringing together contact leads required for this purpose and connecting them to one pole of a voltage source, an evaluation device or a measuring circuit. A disadvantage is that contacting the electrode layers, as known from the prior art, is very complex and not sufficiently stable for long-term, reliable use.

A multilayer actuator is known from EP 2 323 188 B1, the plastic layers of which each have a non-actuating layer and an actuating layer, the non-actuating layer being set up exclusively for electrical contacting (“extension electrodes”) and being mechanically and electrically connected to the actuating layer. The actuation layer is the layer that comprises so-called drive electrodes that act actuatorily.

Although the non-actuating layer and the actuating layer may be of equal thickness, the non-actuating layer is preferably thicker than the actuating layer and made from a different material. Contact electrodes for electrically connecting adjacent layers to different poles of a voltage source are incorporated into the non-actuating layer. The layers are formed from a metal or a metal alloy, which means that only elongations of <10% of the individual plastic layers are possible in a film plane.

In addition, the transducer known from EP 2 323 188 B1 is a so-called stacked actuator, in which movement is only possible in thickness direction of the plastic layers.

### SUMMARY

The invention relates to a dielectric transducer (1; 1a; 1b) for use in a sensor, actuator or generator comprising a plurality of layers of transducer foils (2, 3, 4; 2a, 3a, 4a; 2b, 3b, 4b, 20), wherein an electrically contactable and conductive layer forming an electrode layer (6, 7; 6a, 7a; 6b, 7b, 20) is applied to at least one side of each transducer foil (2, 3, 4; 2a, 3a, 4a; 2b, 3b, 4b, 20). Expediently, at least two contact elements (11, 12; 11a; 11b) are provided, each of which is arranged at least partially in a recess (9, 10; 9a) or in a through-channel and extends over at least one layer of transducer foils (2, 3, 4; 2a, 3a, 4a; 2b, 3b, 4b, 20), adjacent electrode layers (6, 7; 6a, 7a; 6b, 7b, 20) being electrically conductively connected to different contact elements (11, 12; 11a; 11b). Since adjacent electrode layers are connected to different contact elements, intended use is possible, and bringing together several contact lines is advantageously not necessary. Furthermore, the invention relates to a method for producing a multilayer dielectric transducer for use in a sensor, an actuator or a generator, as well as an actuator, a sensor or a generator.

### DETAILED DESCRIPTION

The object of the present invention is to design a multilayer dielectric transducer of the afore-mentioned type, which is particularly simple in construction and can be used in a permanently reliable and fail-safe manner.

According to the invention, the object is achieved in that at least two contact elements are provided, each of which is at least partially arranged in a recess or in a through-channel and extends over at least one layer of transducer foils, adjacent electrode layers being electrically conductively connected to different contact elements.

A single contact element can be provided for each pole, which is electrically conductively connected to the electrode layers to be contacted, for example by material, form and/or force locking. If two contact elements are provided, one can be connected to a positive pole and the second to a negative pole of a voltage source, an evaluation device or a measuring circuit. Since adjacent electrode layers are connected to different contact elements they can be used as intended, and it is advantageously not necessary to bring together several contact lines.

A particularly fail-safe transducer comprises several contact elements, some of which can be connected or are connected to the positive pole and others to the negative pole of a voltage source, an evaluation device or a measuring circuit. A through-channel extends from one side of the transducer to an opposite side, in particular with a directional component perpendicular to a longitudinal direction of the transducer, for example in thickness direction, and a recess is preferably formed as a blind hole.

Although it is conceivable that the transducer according to the invention is designed as a stack transducer whose transducer foils can be deflected in use perpendicular to a foil plane, the dielectric transducer according to the invention is preferably a membrane transducer, that means a transducer whose transducer foils can be deflected in use in a foil plane. During deflection, elongations in the longitudinal direction of up to 100% are possible.

Furthermore, the object of the present invention is to design a method of the type afore-mentioned, which enables simple and particularly process-stable manufacture of a multilayer dielectric transducer.

According to the invention, the object is achieved in that providing at least one of the transducer foils with a through hole and laminating a plurality of transducer foils to form the transducer, or laminating a plurality of transducer foils to form the transducer and afterwards provided with at least two recesses and/or through-channels provided for receiving contact elements.

Either the transducer foils provided with a conductive layer are provided with a through hole before their lamination and are afterwards laminated, or recesses or through-channels are provided in an already laminated transducer foil stack. In the first case, a transducer may be formed by a plurality of specially processed transducer foils, whereas through-openings of a plurality of adjacent laminated transducer foils form through-holes or recesses. Conceivably, not every transducer film is provided with a through hole. For example, upper and/or lower cover layers may be provided.

In the second case, a transducer can be easily manufactured from a standardized semi-finished product.

Lamination can be achieved, for example, by bonding adjacent transducer foils together in edge areas.

If a transducer foil is formed from a material comprising polysiloxane (“silicone”), surface activation by means of plasma is conceivable so that a material bond is formed when two activated surfaces of two adjacent transducer foils are getting into contact.

Expediently, at least one of the contact elements extends into the transducer in thickness direction, or comprises a coating which covers an inner side of the recess or the through-channel. Advantageously, a particularly compact multilayer transducer is created, the contact elements of which are at least partially incorporated in the layers. To apply a voltage to operate the transducer, only two contact elements, which may protrude from a stack of transducer foil layers, for example, need to be contacted. Furthermore, in addition to providing an electrical contacting capability, the contact elements can provide stabilization of a stack of layers. For this purpose, the contact elements can be formed by filling recesses or through-channels in the transducer with an in particular liquid or viscous, curable and electrically conductive material. The recesses and/or the through-channels are symmetrical, preferably rotationally symmetrical.

It is conceivable that several recesses or passage channels are different from each other. For example, one recess or passageway may be circular-cylindrical in shape, while another recess or passageway is cylindrical with a rectangular, triangular or star-shaped base.

In one embodiment of the invention, at least one of the contact elements is stair-shaped or comb-shaped. In a comb-like configuration, the contact element has a plurality of teeth extending into the layers, which are of different lengths and each of which contacts at least one electrode layer, preferably a plurality of layers. Since an electrode layer is contacted by several teeth, a particularly good electrical connection between the contact element and the electrode layers is ensured. Contact losses at one tooth can be compensated by another tooth. If the contact element is stair-shaped, the steps can cause the contact element to taper in one layer direction or, in particular, be arranged linearly offset from one another.

It is also conceivable for the contact element to be formed as a substantially oblique, stepped cylinder.

In a further embodiment of the invention, the electrode layer comprises a non-metallic material or is made of a non-metallic material, in particular carbon, preferably carbon particles embedded in a plastic matrix. Advantageously, a stable and electrically conductive coating is formed. If carbon embedded in a plastic matrix is used, a particularly stretchable electrode layer is formed. An actuator, sensor or generator having such an electrode layer can be stretched more than 10%, even up to 100%, in a foil plane in a longitudinal direction without damaging the electrode layer. It is advantageous if the the transducer foil is formed of polysiloxane and coated with an electrode layer comprising carbon.

It is conceivable that the electrode layer is made of an electrically conductive non-metal, for example an electrically conductive plastic.

Conveniently, each transducer foil comprises at least one surface area in which the electrode layer is interrupted. A safety area is created which is electrically non-conductive. Incorrect contacting of an electrode layer with one of the contact elements, which would destroy the transducer, can be advantageously prevented.

In one embodiment of the invention, a contact area in which one of the contact elements is electrically and mechanically connected to one of the electrode layers is provided, the contact region preferably extending at least partially in the circumferential direction of the contact element. Advantageously, the transducer foils are particularly easy to connect to the contact element.

It is conceivable that the contact area is at least partially covered with a layer which is provided, for example, to improve contact and/or adhesion of the electrode layer with one of the contact elements. If the contact area extends at least partially in the circumferential direction of the contact element, a particularly large contact area is created, which can advantageously ensure particularly good contacting, which can also be produced with particular process reliability.

In one embodiment of the invention, the transducer foils have a thickness between 5 μm and 200 μm, in particular between 10 μm and 100 μm, particularly preferably between 20 μm and 50 μm, and/or are made of a polymer material comprising polysiloxane. Polysiloxane is a very stretchable material, which allows deflections of a transducer according to the invention of up to 100% in the longitudinal direction of a transducer foil.

In a further embodiment of the invention, the thickness of an electrode layer is between 500 nm and 100 μm, preferably between 1 μm and 50 μm, particularly preferably between 1 μm and 5 μm. These thicknesses have been found to be advantageous to allow a particularly compact design and to ensure a damage-free deflection of the transducer foil in a foil plane of >10%, preferably between 15% and 40%, in particular up to 100%. Further advantageously, sais layer thickness is sufficiently large to ensure particularly good current flow through the electrode layers when using the dielectric transducer.

In one embodiment of the invention, adjacent transducer foils are connected to one another in edge areas. The connection is preferably a full-surface material bond, in particular by using an adhesive.

It is conceivable that surface activation of edge areas of adjacent transducer foils is carried out, for example by plasma, whereby a preferably full-surface material bond is formed when adjacent edge areas come into contact.

It is also conceivable that adjacent transducer foils are bonded to each other over the entire surface after a surface activation. Advantageously, no adhesive is required. The stiffness of a stack of transducer foils joined in this way is comparable to that of a stack of transducer foils whose adjacent transducer foils are joined together only at the edges. Advantageously, a particularly long-lasting dielectric transducer is formed.

In one embodiment of the invention, a contact surface of the contact element with one of the electrode layers is arranged in a plane that is parallel to a longitudinal direction of the transducer. Since a dielectric transducer usually experiences a particularly large deflection in a longitudinal direction, i.e. in the layer direction, it is advantageously ensured that no detachment of the contact element from the electrode layer occurs.

In a further embodiment of the invention, between 2 and 100, in particular between 2 and 50, preferably between 2 and 20 transducer foils are provided. Advantageously, both transducers with a large and a small number of layers can be produced.

In one embodiment of the invention, a means for stiffening as well as for electrical contacting of the transducer with an electrical or electronic component is provided on one side or on two opposite sides, the stiffening and contacting means being designed in particular as a printed circuit board. A semi-finished product is created for the manufacturing of an actuator or a sensor. Advantageously, standardization for certain applications is possible.

Manufacturing costs are reduced.

In another embodiment of the invention, at least two of the transducer foils are provided with through-holes of different size, shape and/or orientation in a transducer foil plane. Advantageously, a cross-section or change in cross-section in thickness direction of a recess or through-channel can be tailored. For example, through-holes of adjacent transducer foils can be offset from each other to form a particularly large contact area with an electrode layer. This can form a substantially skew-cylindrical recess having multiple cylinder segments arranged in a stair-like manner, with steps forming contact areas.

It is expedient that each electrode layer is formed in one piece and/or has a constant thickness.

In one embodiment of the method according to the invention, the transducer foils are laminated offset from one another in a longitudinal direction in such a way that adjacent through openings are offset from one another. This enables production by an additive process, in which identical semi-finished products can be used, i.e. a certain number of transducer foils depending on the application case. By laminating them, a particularly durable bond between adjacent transducer foils is achieved.

In a further embodiment of the method according to the invention, surface areas are provided which are not covered with the electrically contactable and conductive layer. Advantageously, faulty contacting is prevented.

More conveniently, the method according to the invention is provided for fabricating a dielectric transducer for use in a membrane actuator, a membrane sensor, or a membrane generator.

### BRIEF DESCRIPTION OF THE DRAWINGS

Embodiments of the invention are to be explained in more detail below on the basis of examples with reference to the non-limiting figures. It is shown:

FIG. 1A a first embodiment of a transducer according to the invention,

FIG. 1B detailed view of the first embodiment,

FIG. 2A further embodiment of a transducer according to the invention,

FIG. 2B another embodiment of the transducer,

FIG. 3A a particular embodiment of a transducer according to the invention,

FIG. 3B another specific embodiment of the transducer.

### DETAILED DESCRIPTION OF THE PREFERRED EMBODIMENTS

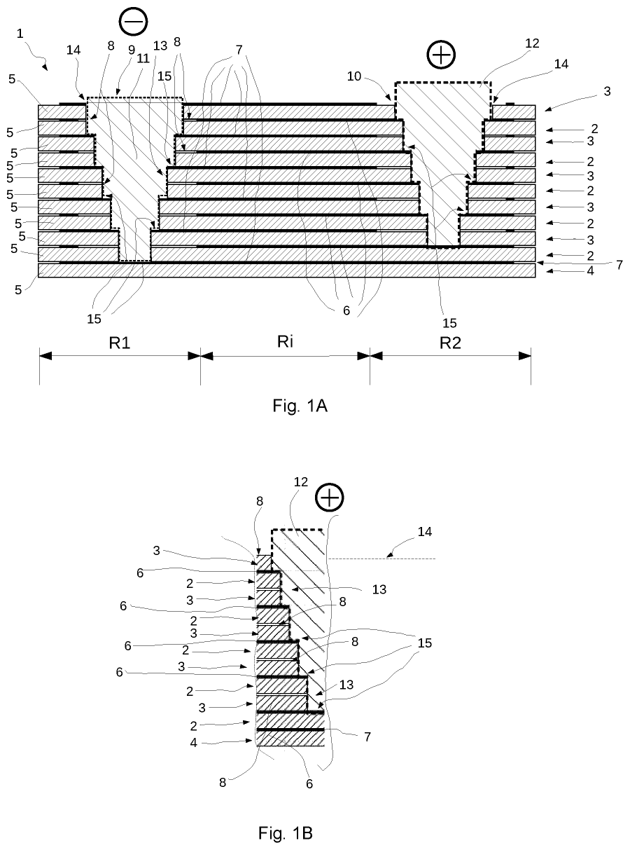

A dielectric transducer (1) shown schematically in a cut side view in FIG. 1a has ten layers of transducer foils (2, 3) and a transducer foil (4) forming a cover layer, each transducer foil (2-4) having a foil (5) formed from silicone and an electrode layer (6, 7) which is applied to the foil (5) by a coating process. Each electrode layer (6,7) is formed of a non-metallic material having carbon particles embedded in a plastic matrix.

In edge areas (R1, R2), adjacent transducer foils (2-4) are bonded to each other over the entire surface, preferably by an adhesive. In an inner area Ri, adjacent transducer foils (2-4) lie against each other over the entire surface.

In surface areas (8) the electrode layer (6, 7) is interrupted, i.e. in these areas the transducer foils (2-4) have no electrode layer (6, 7).

Sections of rotationally symmetrical recesses (9, 10) with a circular cross-section and a staircase-shaped taper perpendicular to the individual layers of transducer foils (2-4) are provided in the transducer (1) in thickness direction, said layers of transducer foils are intended to be filled with a flexible, electrically conductive filling material to form a contact element (11, 12) in each case. The negative pole (−) of a controllable voltage source can be applied to the contact element (11), and the positive pole (+) to the contact element (12).

Transducer foils (2, 3) adjacent in pairs form a step (13), on whose side facing an opening (14) of the recess (9, 10) a contact region (15) of the electrode layer (6, 7) extending in the circumferential direction of the recess (9, 10) is formed, in which the contact elements (11, 12) located in the recesses are electrically and mechanically, in particular by frictional, material and/or positive locking, connected to the electrode layer (6, 7). The electrode layer (6) is connected to the contact element (12), the electrode layer (7) to the contact element (11). This ensures that adjacent electrode layers (6, 7) are electrically connected to opposite poles and that an intended use of the transducer (1) is possible, for example in an actuator, a sensor or a generator. Faulty contact is ensured in particular by the electrode-free surface areas (8).

Details of a transducer (1) according to FIG. 1a are shown in FIG. 1b in a cut side view.

A transducer shown in FIG. 1 can be manufactured by coating foils (5) with an electrode layer (6,7), laminating a plurality of transducer foils (2-4), and forming the recesses (9,10) by a subtractive process, such as laser ablation.

It is conceivable that several transducer foils (2-4) provided with a passage in thickness direction are laminated, for example offset from one another in longitudinal direction of the foil, in such a way that passages of several transducer foils (2-4) arranged one above the other form a recess (9, 10). It is also conceivable that, for production, a plurality of transducer foils (2-4) provided with a passage in thickness direction are laminated in such a way that adjacent passages in the thickness direction are arranged one above the other, the passages having diameters different from one another.

Although the recesses (9, 10) of a transducer (1) shown in FIG. 1 are identical, this is not necessary. Different recesses are conceivable.

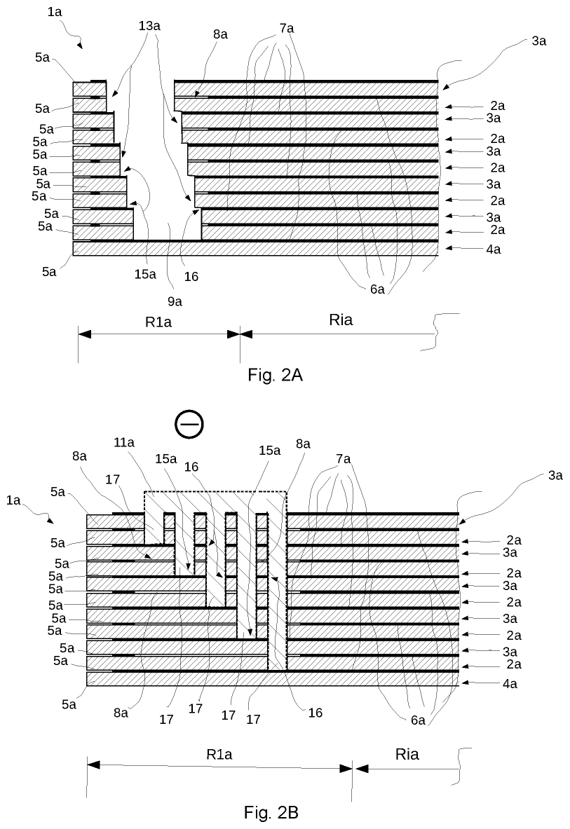

Reference is now made to FIG. 2, where identical or equal-acting parts are designated with the same reference number as in FIG. 1, and the letter a is added to the respective reference number.

A dielectric transducer (1a) shown schematically in a cutaway side view in FIG. 2a, in which no contact elements are shown for reasons of clarity, differs from the one shown in FIG. 1 in that a recess (9a) is formed obliquely cylindrically with a circular cross section and steps (13a). In this embodiment, contact areas (16) can be seen in which contact is possible exclusively with end faces of the electrode layers (6a, 7a).

A dielectric transducer (1a) shown schematically in a cutaway side view in FIG. 2b differs from those shown in FIGS. 1 and 2a in that a contact element (11a) shown in dashed lines is of comb-shaped design, with five comb teeth (17) each extending over several transducer foils (2a, 3a). The longer a comb tooth (17) is, the more circumferential end-face contact areas (16) are formed.

It is conceivable that instead of a contact element (11, 12; 11a, 12a), an electrically conductive layer is formed into a recess (9, 10; 9a, 10a) which is electrically conductively connected to electrode layers (6, 7; 6a, 7a).

It is also conceivable that a contact element (11, 12; 11a, 12a) is a prefabricated component which is inserted into recesses (9, 10, 9a, 10a) for contacting with electrode layers (6, 7; 6a, 7a) and is held by a clamp connection. Other types of connection are conceivable, in particular a material, form-fit and/or force-fit connection.

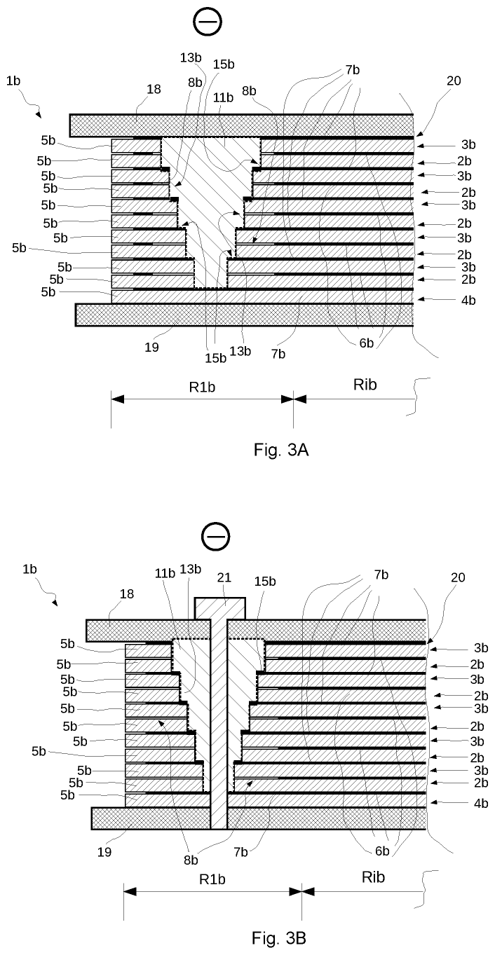

Reference is now made to FIG. 3, where identical or equal-acting parts are designated by the same reference number as in FIGS. 1 and 2, and the letter b is added to the respective reference number.

In a particular embodiment of a transducer according to the invention shown in FIG. 3a, a control board (18) and a carrier plate (19) are provided, between which several layers of transducer foils (2b, 3b) are arranged. A connection with the control board (18), the carrier plate (19) and/or a contact element (11b, 12b) can be material-, force- and/or form-fitted. For this purpose, an upper electrode layer (20) forms a contact layer to the control board (18) and in this embodiment is connected to the control board (18) by a material bond.

In a particular embodiment of a transducer according to the invention shown in FIG. 3b, a control board (18) and a carrier plate (19) are provided, between which several layers of transducer foils (2b, 3b) are arranged. The stack is clamped between the control board (18) and the carrier plate (19) and held by a screw connection, a retaining screw (21) being passed through a contact element (11b, 12b).

To produce a transducer (1b) shown in FIG. 3b, the transducer fioils (2b, 3b) can be provided with a through-channel—before or after their lamination—which extends in thickness direction.

It is conceivable that several layers of transducer foils (2, 3; 2a, 3a; 2b, 3b) are clamped or clamped between a control board (18) and a carrier plate (19) in an exclusively force-fit manner.

It is also conceivable that adjacent transducer foils (2, 3; 2a, 3a; 2b, 3b) are bonded to one another in an inner area (Ri; Ria; Rib).

It is also conceivable that a control board (18) has a contact element (11b) which, when a board (18) is connected to transducer foils (2b-4b, 20), dips into a recess (11b) and makes electrically conductive contact with electrode layers (6b, 7b).

It is understood that all combinations of features of the embodiments shown in FIGS. 1 to 3 are conceivable.

1. A dielectric transducer for use in a sensor, actuator or generator comprising a plurality of layers of transducer foils, wherein on at least one side of each transducer foil an electrically contactable and conductive layer forming an electrode layer is applied,
characterized
in that at least two contact elements are provided, each of which is arranged at least partially in a recess or in a through-channel and extends over at least one layer of transducer foils, adjacent electrode layers being electrically conductively connected to different contact elements.

2. The dielectric transducer according to claim 1,
characterized
in that at least one of the contact elements extends into the transducer in thickness direction, or comprises a coating which covers an inner side of the recess or of the through-channel.

3. The dielectric transducer according to claim 1,
characterized
in that at least one of the contact elements is stair-shaped or comb-shaped.

4. The dielectric transducer according to claim 1,
characterized
in that the electrode layer comprises a non-metallic material or is made of a non-metallic material, in particular carbon, preferably carbon particles embedded in a plastic matrix.

5. The dielectric transducer according to claim 1,
characterized
in that each transducer foil comprises at least one surface area in which the electrode layer is interrupted.

6. The dielectric transducer according to claim 1,
characterized
in that the transducer foils have a thickness of between 5 μm and 200 μm, in particular between 10 μm and 100 μm,
particularly preferably between 20 μm and 50 μm, and/or are made of a polymer material comprising polysiloxane.

7. The dielectric transducer according to claim 1,
characterized
in that the thickness of an electrode layer is between 500 nm and 100 μm, preferably between 1 μm and 50 μm, particularly preferably between 1 μm and 5 μm.

8. The dielectric transducer according to claim 1,
characterized
in that adjacent transducer foils are connected to one another in edge areas.

9. dielectric transducer according to claim 1,
characterized
in that between 2 and 100, in particular between 2 and 50, preferably between 2 and 20 transducer foils are provided.

10. The dielectric transducer according to claim 1,
characterized
in that a means for stiffening as well as for electrical contacting of the transducer with an electrical or electronic component is provided on one side or on two opposite sides, the stiffening and contacting means being designed in particular as a printed circuit board.

11. A method of producing a multilayer dielectric transducer for use in a sensor or an actuator, in which at least one side of a foil formed from a flexible material is covered at least zonally with an electrically contactable and conductive layer forming an electrode layer to form a transducer foil,
characterized
in that at least one of the transducer foils is provided with a through hole and a plurality of transducer foils are laminated to form the transducer, or a plurality of transducer foils are laminated to form the transducer and are afterwards provided with at least two recesses and/or through-channels provided to receive contact elements.

12. The method according to claim 11,
characterized
in that the transducer foils are laminated offset from one another in a longitudinal direction in such a way that adjacent through openings are offset from one another.

13. The method according to claim 11,
characterized
in that surface regions are provided which are not covered with the electrically contactable and conductive layer.

14. The method according to claim 11,
characterized
in that recesses and/or a through-channel for forming a contact element are filled with a rigid or flexible, preferably curable, electrically conductive material in such a way, or inner walls are coated with an electrically conductive layer in such a way, or a contact element is introduced into the recesses and/or the through-channels in such a way that an electrical contact between the contact element and the through-channel is established.

15. A sensor, actuator or generator comprising a dielectric transducer according to claim 1 and/or manufactured by a method according to claim 11.
